(19) United States
(12) Patent Application Publication
(10) Pub. No.: US 2011/0233599 A1
(43) Pub. Date: Sep. 29, 2011

(54) LIGHT-EMITTING DEVICE

(75) Inventor: Takanobu Kamakura, Fukuoka-ken (JP)

(73) Assignee: KABUSHIKI KAISHA TOSHIBA, Tokyo (JP)

(21) Appl. No.: 12/881,437

(22) Filed: Sep. 14, 2010

(30) Foreign Application Priority Data
Mar. 25, 2010 (JP) 2010-070230

(51) Int. Cl. H01L 33/36

(52) U.S. Cl. 257/99; 257/E33.063

(57) ABSTRACT

According to one embodiment, a light-emitting device includes a semiconductor stacked body and a pad electrode. The semiconductor stacked body has a surface and includes a light-emitting layer. The surface has protruding portions. The pad electrode is provided on one of a top surface of the protruding portions and a bottom surface around the protruding portions.

### CROSS-REFERENCE TO RELATED APPLICATIONS

This application is based upon and claims the benefit of priority from the prior Japanese Patent Application No. 2010-070230, filed on Mar. 25, 2010; the entire contents of which are incorporated herein by reference.

### FIELD

Embodiments described herein relate generally to a light-emitting device.

### BACKGROUND

In the case where the top surface of a light-emitting device is the light extraction side and the area of a pad electrode to be wire-bonded is large, the light extraction efficiency decreases because emitted light is blocked.

If a transparent electrode is provided between the pad electrode and a semiconductor stacked body including a light-emitting layer, the pad electrode can be made smaller by spreading carriers in the surface of the light-emitting layer. Accordingly, the light-extraction efficiency can be improved.

However, to secure a bonding strength between a bonding wire and the pad electrode having a flat surface, the pad electrode needs to be bonded with the same material as that of the wire such as an Au alloy because of the unfavorable bonding ability with the material of the transparent electrode such as a conductive oxide. The use of such a material causes a problem of blocking the emitted light. In addition, the size of the flattened bonding wire has such a large diameter of 80 μm to 100 μm that a certain limitation is placed on area reduction of the pad electrode. For this reason, the chip size of a light-emitting device having a light-emitting efficiency of 100 lm/w or higher is usually 200 μm×200 μm or larger.

### BRIEF DESCRIPTION OF THE DRAWINGS

FIG. 1A is a schematic plan view of a light-emitting device according to a first embodiment, FIG. 1B is a schematic cross-sectional view taken along line A-A, and FIG. 1C is a partially enlarged schematic cross-sectional view;

FIG. 2A is a schematic cross-sectional view of a light-emitting apparatus including the light-emitting device according to the first embodiment, and FIG. 2B is a partially enlarged schematic cross-sectional view thereof;

FIGS. 3A to 3F are process sectional views showing a method for manufacturing the light-emitting device according to the first embodiment;

FIGS. 4A to 4C are process sectional views to form a pad electrode, and FIGS. 4D and 4E are partially enlarged schematic plan views;

FIGS. 5A to 5D are process sectional views showing a method for manufacturing a light-emitting device according to a second embodiment, and FIGS. 5E and 5F are schematic plan views;

FIGS. 6A to 6G are process sectional views showing a method for manufacturing a light-emitting device according to a third embodiment, and FIGS. 6H and 6I are schematic plan views;

FIG. 7A is a schematic plan view of a light-emitting device according to a fourth embodiment, and FIG. 7B is a schematic cross-sectional view taken along line E-E;

FIG. 8 is a schematic cross-sectional view of a light-emitting device according to a fifth embodiment;

FIG. 9A is a schematic plan view of a light-emitting device according to a sixth embodiment, and FIG. 9B is a schematic cross-sectional view taken along line F-F; and

FIGS. 10A to 10D are schematic cross-sectional views of the proximity of an alloy layer.

### DETAILED DESCRIPTION

In general, according to one embodiment, a light-emitting device includes a semiconductor stacked body and a pad electrode. The semiconductor stacked body has a surface and includes a light-emitting layer. The surface has protruding portions. The pad electrode is provided on one of a top surface of the protruding portions and a bottom surface around the protruding portions.

Embodiments of the invention will now be described with reference to the drawings.

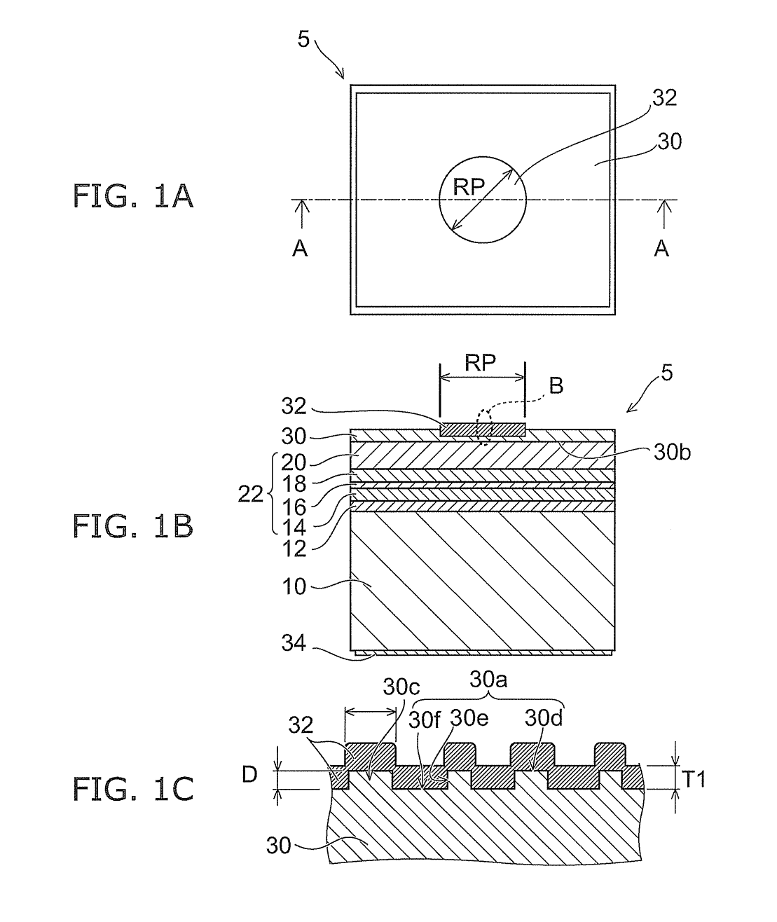

FIG. 1A is a schematic plan view of a light-emitting device according to a first embodiment of the invention, FIG. 1B is a schematic cross-sectional view taken along line A-A, and FIG. 1C is a partially enlarged schematic cross-sectional view of a region B.

A semiconductor stacked body 22 is provided on a substrate 10 via a bonding layer 12. A transparent electrode 30 and a pad electrode 32 are stacked on the semiconductor stacked body 22 in this order. In addition, a lower-portion electrode 34 is provided on a back-side surface of the substrate 10. The pad electrode 32 has a shape of a circle with a diameter RP, for example.

The semiconductor stacked body 22 includes, at least, a first-conductivity-type cladding layer 14, a light emitting layer 16, a second-conductivity-type cladding layer 18, and a second-conductivity-type current-diffusing layer 20 (if needed), and the like which are stacked above the substrate 10. Note that, if the substrate 10 is made of a transparent material, the light absorption in the substrate 10 can be reduced and thus the light-extraction efficiency can be enhanced.

FIG. 1C is an enlarged view of the region B including the transparent electrode 30 and the pad electrode 32. A first surface 30a of the transparent electrode 30 includes a top surface 30d of protruding portions 30c with a height (a step difference) D, a side surface 30e of the protruding portions 30c, and a bottom surface 30f provided around the protruding portions 30c. The pad electrode 32 is provided on the top surface 30d of the protruding portions 30c and the bottom surface 30f. Further, in FIG. 1C, the pad electrode 32 is also in contact with the side surface 30e of the protruding portions 30c. Moreover, a second surface 30b of the transparent electrode 30 on a side opposite to the first surface 30a forms an ohmic contact with the semiconductor stacked body 22.

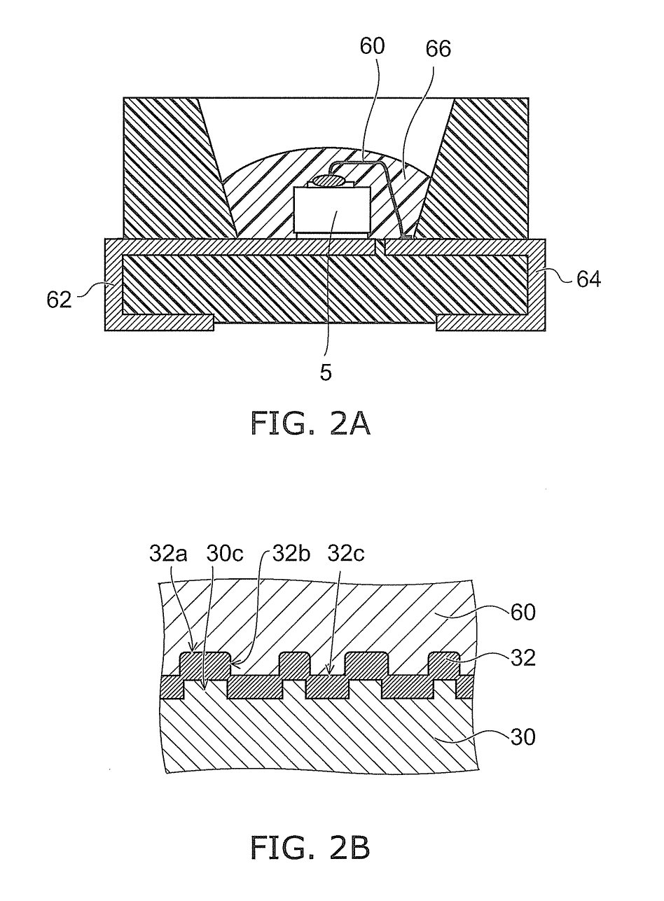

FIG. 2A is a schematic cross-sectional view of a light-emitting apparatus including the light-emitting device according to the first embodiment, and FIG. 2B is a partially enlarged schematic cross-sectional view thereof.

A bonding wire 60 made of Au or the like is bonded by thermo-compression method to the pad electrode 32 of a light-emitting device 5 provided on a first lead 62 while ultrasonic waves are being applied to the bonding wire 60 via a capillary or the like. In addition, the bonding wire 60 is bonded by thermo-compression method to an end portion of a second lead 64 in a similar process.

The surface of the pad electrode 32 has a recessed and protruding configuration. As shown in FIG. 2B, the tip portion of the bonding wire 60 is bonded by thermo-compression method to a top surface 32a of the protruding portions, a side surface 32b of the protruding portions, a bottom surface 32c around the protruding portions 30c, and the like while biting into the recessed and protruding portion of the pad electrode 32. The tip portion of the bonding wire 60 made of Au is locally heated to around 1000° C. by electric discharge and formed into a ball shape by surface tension and the like.

The ball-shaped tip of the bonding wire 60 is pressed onto the top surface 32a of the pad electrode 32 by the tip portion of the capillary. In this case, the ball-shaped tip portion of the wire is squashed and flattened out by being pressed onto a wide bonding area including the top surface 32a of the protruding portions, the side surface 32b of the protruding portions, the bottom surface 32c around the protruding portions 30c, and the like. In addition, the ball-shaped tip portion of the bonding wire 60 bites into a step difference of the protruding portions 30c, thereby producing an anchoring effect. Accordingly, the wire-bonding strength can be easily enhanced in comparison to a pad electrode with a flat surface.

According to an experiment conducted by the inventors, the following was found. The discharge current, the load, and the ultrasonic output required for the wire bonding can be reduced and also the diameter of the flattened wire can be decreased in the case where the pad electrode 32 is made of Au to have a thickness (T1) ranging from 20 nm to 200 nm; the height D of the protruding portions 30c is set at 180 nm; and an average pitch of the protruding portions of the island-shaped pad electrode 32 is set in a range from 10 nm to 3 μm. On the other hand, in the case of a flat pad electrode with no microscopic recessed and protruding portions formed thereon, the ultrasonic output and the like needed to be increased, and an Au wire with a diameter ranging from 15 μm to 30 μm was flattened out to have a diameter ranging from 80 μm to 100 μm. For this reason, it was necessary to make the pad electrode larger in size than the flattened wire. In contrast, according to the first embodiment, the diameter of the flattened wire could be made not more than 60 μm. In addition, even when the thickness of the pad electrode 32 was made as small as 20 nm, the bonding strength could be secured. Accordingly, the size of the pad electrode 32 could be reduced, and the light-extraction efficiency (luminance) could be enhanced.

As shown in FIG. 2A, phosphor particles may be dispersed and arranged in a resin layer 66 provided to cover the light-emitting device 5. In this case, the setting of the wavelength of the light from the light-emitting device 5 in a range from the ultraviolet light to the violet-blue light makes it possible to emit wavelength-converted light by the phosphor particles. Therefore, white light can be obtained as mixed light of the light from the light-emitting device 5 and the wavelength-converted light.

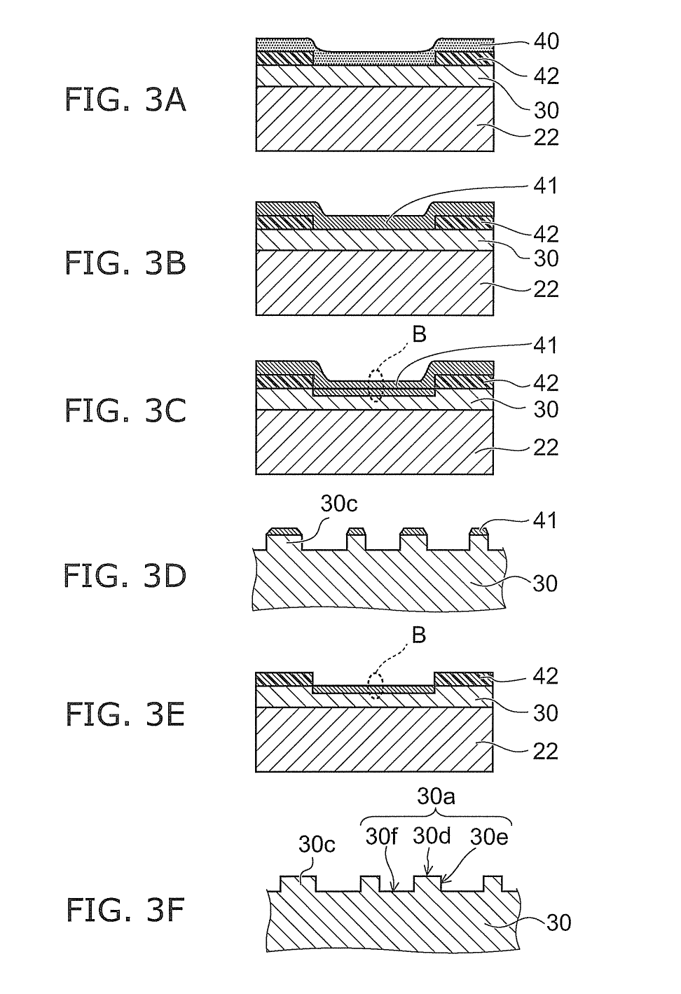

FIGS. 3A to 3F are process sectional views showing a method for manufacturing a light-emitting device according to the first embodiment. The material of the semiconductor stacked body 22 may be InGaAlN-based, InAlGaP-based, AlGaAs-based, or the like, but it is not limited thereto. In the specification, the InGaAlN-based material refers to a material represented by a composition formula InₓGa_{y}Al_{1-x-y}N (0≦x≦1, 0≦y≦1, 0≦z≦1, x+y≦1) and may contain an element to be a doner or an acceptor. Likewise, the InAlGaP-based material refers to a material represented by a composition formula Inₓ(Al_{y}Ga_{1-y})₁₋ₓP (0≦x≦1, 0≦y≦1) and contains an element to be a doner or an acceptor. In addition, the AlGaAs-based material refers to a material represented by a composition formula AlₓGa₁₋ₓAs (0≦x≦1) and contains a doner or an acceptor.

In FIGS. 3A to 3F, the semiconductor stacked body 22 is made of an InGaAlN-based material. In addition, although the second conductivity type is assumed to be the p-type, the invention is not limited thereto and the second conductivity type may be the n type. Ti is thinly provided in a thickness of several nanometers on a p-type GaN contact layer provided above a p type cladding layer as necessary. Then, the transparent electrode 30 made of ITO (Indium Tin Oxide), ZnO, or the like is formed with a thickness of several hundred nanometers by the sputtering method or the like. In this case, using the lift-off method enables the transparent electrode 30 to be formed only in the necessary region.

Subsequently, a film of a photo-resist material is formed by the spin coating method in a thickness of 200 nm, for example. Then, an opening is formed only in a region where the pad electrode 32 is to be formed, by the PEP method or the like, followed by baking in a nitrogen atmosphere and at 160° C.

Then, a block copolymer 40 is coated by the spin coating method (FIG. 3A) in a thickness of 200 nm. The block copolymer 40 is prepared by mixing polystyrene (PS)-polymethylmethacrylate (PMMA) and PMMA homopolymer in equal amounts, for example, and using PS homopolymer and propyleneglycol monomethyl ether acetate (PGMEA) as solvents. The block copolymer 40 can be phase-separated by baking at, for example 110° C., and annealing at 250° C. in a nitrogen atmosphere. Specifically, PS and PMMA are agglutinated in a self-organized manner to form a PS layer 41 in a thickness from several tens nanometers to several hundreds nanometers (FIG. 3B). If the composition ratio of PS and PMMA is changed, the particle diameter size and the occupancy rate of the particles can be changed. In this embodiment, the occupancy rate is assumed to be around 50%.

Subsequently, RIE (reactive ion etching) process is performed as shown in FIG. 3C, so that PMMA is removed by selective etching. FIG. 3D is an enlarged view of the region B. The PS layer 41 is left with island-shaped patterns distributed at an average pitch ranging from 10 nm to 3 μm. If the average pitch is smaller than 10 nm, the ball at the tip portion of the bonding wire can not bite into the protruding portion sufficiently. If the average pitch is larger than 3 μm, the surface of the pad electrode 32 becomes flatter, resulting in insufficient bonding strength of the bonding wire. Note that, the shortest distance among the distances from one of the islands to the neighboring islands is defined as a pitch PI. In addition, assuming that the island-shaped patterns having random shapes are replaced with circles having equal areas, the distance above is defined as a distance between the centers of two of the circles. Thus, the average pitch of the island-shaped patterns is defined by the average value of the pitches PI.

Then, RIE process is performed using a gas containing Cl (chlorine) as the main component, for example, using the island-shaped PS layer 41 as a mask, so that the first surface 30a with the island shaped protruding portions 30c as shown in FIG. 3E is formed in the transparent electrode 30. Moreover, the RIE using a gas not containing chlorine may be performed due to influences on the reliability of the device and the like. The type of gas may be selected appropriately in accordance with the materials. Subsequently, the PS layer 41 is removed from regions where the pad electrode is to be formed. Thus, as shown in the enlarged view (of the region B) of FIG. 3F, the first surface 30a of the transparent electrode 30 is obtained, which is constituted of the top surface 30d of the protruding portions 30c, the side surface 30e of the protruding portions 30c, and the bottom surface 30f around the protruding portions 30c.

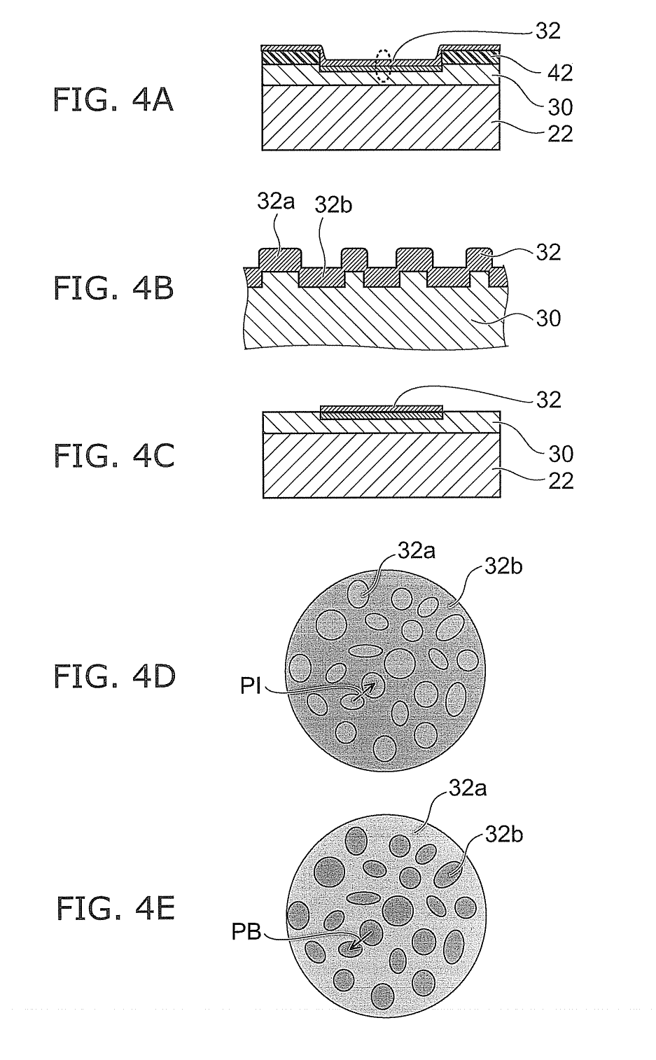

FIGS. 4A to 4C are process sectional views to form a pad electrode, and FIGS. 4D and 4E are partially enlarged schematic plan views.

As shown in FIG. 4A, a pad electrode material containing Au, Al, or the like is formed on the entire surface. FIG. 4B is a partially enlarged schematic cross-sectional view. Pad electrodes 32a and 32b on which patterns are transferred are formed on the first surface 30a of the transparent electrode 30. In this case, if Ti with a thickness of 2 nm, for example, is provided on the transparent electrode 30, the adhesion can be enhanced. In addition, if a high-melting-point metal film, such as Rh and Hf, is provided with a thickness of several tens nanometers between Ti and Au, the film can serve as a barrier film capable of suppressing the diffusion of the metals into each other and the forming an alloy by the metals.

Then, as FIG. 4C shows, the pad electrode material outside a region to be formed into the pad electrode is removed by the lift-off method.

FIG. 4D is a schematic plan view of FIG. 4B. If the molecular-amount proportion of PS and PMMA is 1:3, the protruding portions 30c form an island-shaped pad electrode 32 and the surrounding areas form a pad electrode 32 which constitutes continuous bottom surfaces 30f. In addition, if the molecular-amount proportion of PS and PMMA is 3:1, the PMMA is agglutinated in island shapes, and a reversed pattern can be obtained. Specifically, the protruding portions 30c form a mesh-like pad electrode 32 like the top surface shown in FIG. 4E, and the pad electrode 32 constituting the bottom surfaces 30f of the opening portions is exposed. The average pitch of the bottom surfaces 30f can be distributed in a range from 10 nm to 30 μm, for example. Note that, the shortest distance among the distances from one of the bottom surface 30f of the opening portions of the mesh-like protruding portions to the bottom surface 30f of the neighboring opening portions is defined as a pitch PB. In addition, assuming that the bottom surface 30f having random shapes of the opening portions of the mesh-like protruding portions 30c are replaced with circles having equal areas, the distance above is defined as a distance between the centers of two of the circles. Thus, the average pitch of the bottom surface 30f of the opening portions is defined by the average value of the respective pitches PB.

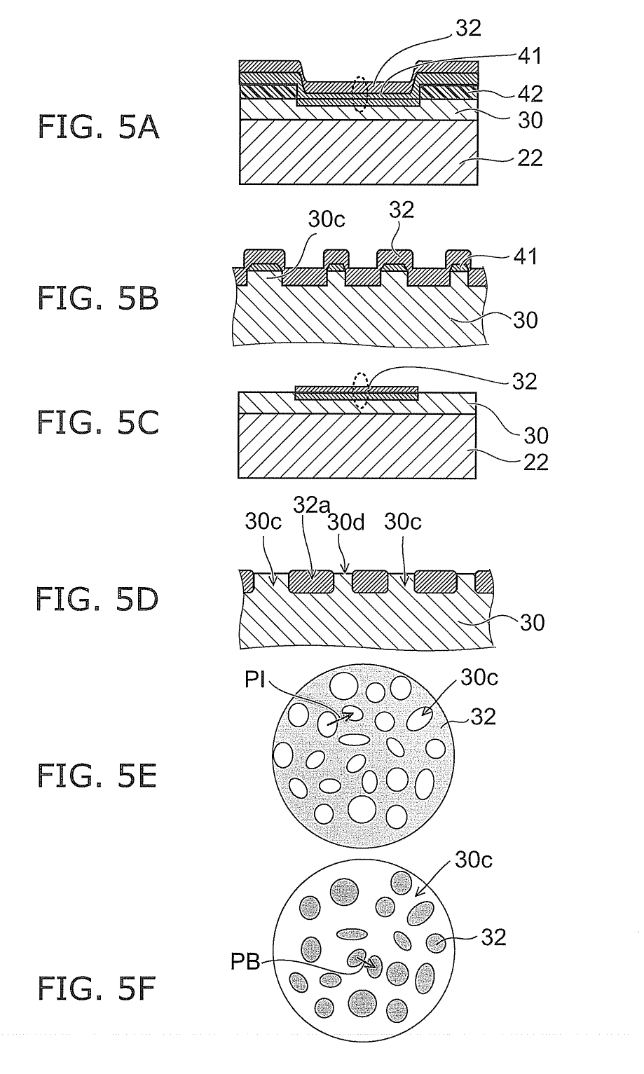

FIGS. 5A to 5D are process sectional views showing a method for manufacturing a light-emitting device according to a second embodiment, and FIGS. 5E and 5F are schematic plan views.

The processes up to the phase separation of the block copolymer and the subsequent RIE process are the same as that of FIGS. 3A to 3C. After that, an Au film forming the pad electrode 32 is formed on the entire surface while the PS layer 41 used as the mask is left (FIGS. 5A and 5B). Then, the photo-resist film 42 is removed, and the Au film and the PS layer 41 outside a region to be formed into the pad electrode are removed.

Further, the PS layer 41 on the protruding portions 30c of the transparent electrode 30 is removed, and accordingly the Au film on the PS layer 41 is also removed. Thus, the structure shown in FIGS. 5C and 5D is obtained. Specifically, the top surface 30d of the protruding portions 30c of the transparent electrode 30 have an island shape, and the pad electrode 32 is provided on the continuous, mesh-like bottom surface 30f in the surrounding area as shown in FIG. 5E. If the PS 41 serving as a mask is not thick enough in this process, a solvent containing SiO₂, for example, may be coated in a thickness of several hundred nanometers before the coating of the block copolymer 40. Note that wire bonding to the surfaces of the pad electrode 32 can be made easier if the pad electrode 32 is protruded from the protruding portions 30c of the transparent electrode 30.

With an increased composition ratio of PS, the surface of protruding portions 30c of the transparent electrode 30 forms a shape like a continuous mesh and has a structure in which a pad electrode 32 provided in the opening portions of the mesh is surrounded. In the second embodiment, light is upwardly transmittable through between the separated portions of pad electrodes 32 from the protruding portions 30c of the transparent electrode 30 except for a region where the flattened wires block the light. Consequently, the light-extraction efficiency (luminance) can be further enhanced.

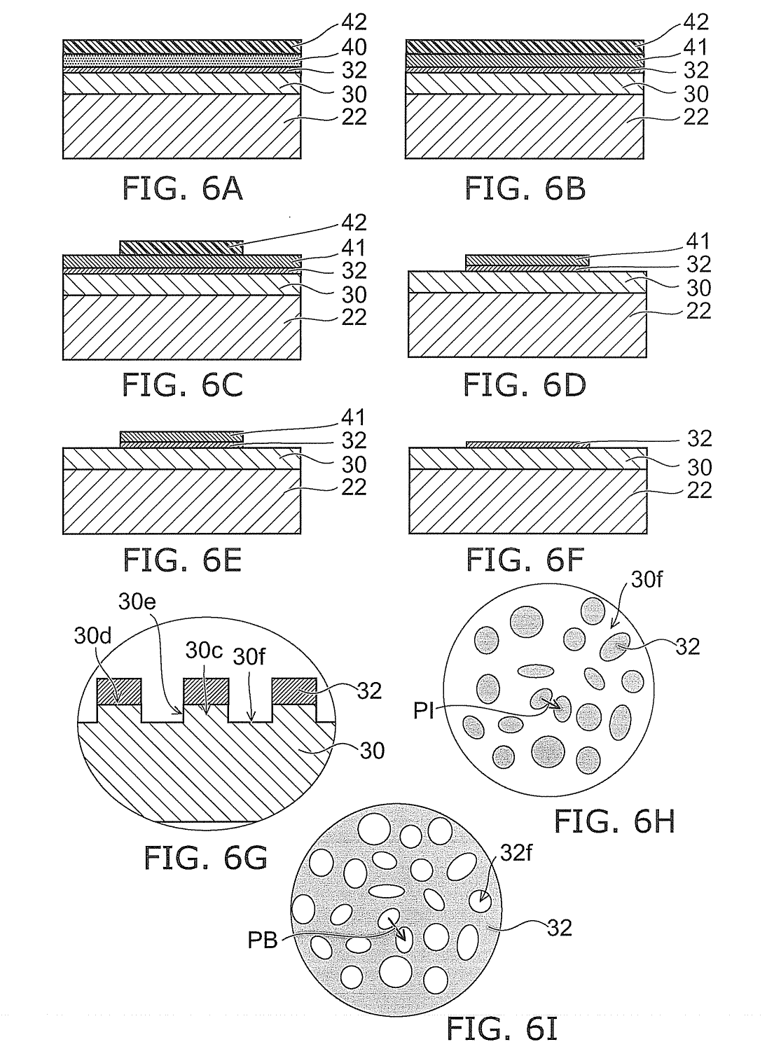

FIGS. 6A to 6G are process sectional views showing a method for manufacturing a light-emitting device according to a third embodiment, and FIGS. 6H and 6I are schematic plan views.

As shown in FIG. 6A, a pad electrode material is formed on the entire surface of the transparent electrode 30. Then, a block copolymer 40 and a photo-resist film 42 are stacked in this order. The block copolymer 40 is phase-separated to form the PS layer 41 (FIG. 6B). Then, the photo-resist film 42 is patterned by the PEP method (FIG. 6C). Then, the PS layer 41 and the pad electrode material outside a region to be formed into the pad electrode are removed (FIG. 6D).

By using the PS layer 41 as a mask, RIE process is performed on the pad electrode 32 containing Au and the like in a gas atmosphere whose major component is Ar, and then RIE process is performed on the transparent electrode 30 in a gas atmosphere whose major component is Cl, for example (FIG. 6E). The RIE using a gas not containing chlorine may be performed due to influences on the reliability of the device and the like. The type of gas may be selected appropriately in accordance with the materials. Then, the PS layer 41 is removed (FIG. 6D). Consequently, a light-emitting device is completed in which the pad electrodes 32 are formed on the top surfaces 30d of the protruding portions 30c of the transparent electrode 30 as shown in FIG. 6G. The transparent electrode 30 is exposed to the bottom surfaces 30f around the protruding portions 30c. The top surface shown in FIG. 6H has a structure in which the protruding portions of the transparent electrode 30 are island-shaped pad electrodes 32. If the PS 41 serving as the mask is not thick enough in this process, a solvent containing, for example, SiO₂ may be coated in a thickness of several hundred nanometers before the coating of the block copolymer 40.

As shown in FIG. 6I, with an increased composition ratio of PS, a top surface 30d of protruding portions 30c forms a shape like a continuous mesh, and the transparent electrode 30 can be formed in the bottom surface of the opening portions. In the third embodiment, light is upwardly transmittable from the bottom surfaces 30f of the transparent electrode 30 except for a region where the flattened wire blocks the light. Consequently, the light-extraction efficiency (luminance) can be further enhanced.

In the third embodiment, the side surfaces of the pad electrode 32 and the side surfaces of the transparent electrode 30 can be in contact with the ball of the bonding wire 60, and thereby can establish more reliable bites. In a region not in contact with the ball, a sealing resin, for example, bites into the recessed and protruding portions, and thereby the adhesion becomes more secure.

Next, the luminance of each of the light-emitting devices according to the first to third embodiments is compared, by an optical simulation, with the luminance of a comparative example having a flat pad-electrode layer (with a thickness of 1 μm) provided on a transparent electrode.

Table 1 shows the improvement rates (%) of the luminance of the light-emitting device according to the first embodiment with respect to the luminance of the light-emitting device according to the comparative example. Note that the pad electrode 32 of the first embodiment is set to have a thickness of 20 nm and the light-transmittance of the pad electrode 32 is set to 30%.

TABLE 1
TRANSMITTANCE: 30%

| SIZE OF | BALL | | BALL | | BALL | |
|---|---|---|---|---|---|---|
| TRANS- | DIAMETER: | | DIAMETER: | | DIAMETER: | |
| PARENT | 80 μm | | 70 μm | | 60 μm | |
| ELECTRODE | PAD DIAMETER (μm) | | | | | |
| (μm) | 110 | 100 | 100 | 90 | 90 | 80 |
| 300 | 1.7% | 1.0% | 1.5% | 0.9% | 1.3% | 0.8% |
| 250 | 2.5% | 1.6% | 2.2% | 1.3% | 1.9% | 1.1% |
| 200 | 4.4% | 2.6% | 3.7% | 2.2% | 3.2% | 1.9% |
| 170 | 6.9% | 4.0% | 5.7% | 3.3% | 4.7% | 2.8% |
| 140 | 13.3% | 7.2% | 10.2% | 5.7% | 8.0% | 4.5% |
| 110 | 51.6% | 19.9% | 28.3% | 13.1% | 18.5% | 9.3% |
| 90 | — | — | — | 43.3% | 60.9% | 21.4% |

Table 1 clearly shows that the improvement effect of luminance becomes larger, as the size of the chip becomes smaller and the size of the transparent electrode 30 (assuming that the transparent electrode 30 has a square shape, and the size is represented by each side length of the square shape) becomes closer to the outer diameter of the pad electrode. In addition, if the diameter of the pad electrode 32 is kept constant, the luminance-improvement rate is enhanced with decrease in the diameter of the flattened ball of the bonding wire 60. In Table 1, the highest luminance-improvement rate (60.9%) is marked in the case where the transparent electrode 30 has a size of a 90 μm square, the diameter of the pad electrode 32 is 90 μm, and the diameter of the flattened ball is 60 μm. Note that the luminance-improvement rate was approximately 80% in the trial manufacture.

Table 2 shows the improvement rates (%) of the luminance of the light-emitting device according to the second embodiment with respect to the luminance of the light-emitting device according to the comparative example. Note that the pad electrode 32 is set to have a thickness of 200 nm and the light-transmittance of the pad electrode 32 is set to 50%.

TABLE 2
TRANSMITTANCE: 50%

| SIZE OF | BALL | | BALL | | BALL | |
|---|---|---|---|---|---|---|
| TRANS- | DIAMETER: | | DIAMETER: | | DIAMETER: | |
| PARENT | 80 μm | | 70 μm | | 60 μm | |
| ELECTRODE | PAD DIAMETER (μm) | | | | | |
| (μm) | 110 | 100 | 100 | 90 | 90 | 80 |
| 300 | 2.8% | 1.7% | 2.4% | 1.5% | 2.1% | 1.3% |
| 250 | 4.2% | 2.6% | 3.7% | 2.2% | 3.1% | 1.9% |
| 200 | 7.3% | 4.4% | 6.2% | 3.7% | 5.3% | 3.1% |
| 170 | 11.5% | 6.7% | 9.5% | 5.6% | 7.8% | 4.6% |
| 140 | 22.1% | 12.0% | 17.0% | 9.5% | 13.3% | 7.5% |
| 110 | 86.0% | 33.2% | 47.1% | 21.9% | 30.8% | 15.5% |
| 90 | — | — | — | 72.1% | 101.4% | 35.7% |

In this case, the highest luminance-improvement rate (101.4°) is marked in the case where the transparent electrode 30 has a size of a 90 μm square, the diameter of the pad electrode 32 is 90 μm, and the diameter of the flattened wire is 60 μm. The luminance-improvement rate was approximately 100% in this experimental trial. Note that, although the pad electrode 32 is separated into island shapes, the diameter of the pad electrode 32 is represented by the outer diameter of the distribution.

Table 3 shows the improvement rates (%) of the luminance of the light-emitting device according to the third embodiment with respect to the luminance of the light-emitting device according to the comparative example. Note that the pad electrode 32 is set to have a thickness of 200 nm and the light-transmittance of the pad electrode 32 is set to 70%.

TABLE 3
TRANSMITTANCE: 70%

| SIZE OF | BALL | | BALL | | BALL | |
|---|---|---|---|---|---|---|
| TRANS- | DIAMETER: | | DIAMETER: | | DIAMETER: | |
| PARENT | 80 μm | | 70 μm | | 60 μm | |
| ELECTRODE | PAD DIAMETER (μm) | | | | | |
| (μm) | 110 | 100 | 100 | 90 | 90 | 80 |
| 300 | 3.9% | 2.4% | 3.4% | 2.1% | 3.0% | 1.8% |
| 250 | 5.9% | 3.6% | 5.1% | 3.1% | 4.4% | 2.7% |
| 200 | 10.3% | 6.2% | 8.7% | 5.2% | 7.4% | 4.4% |
| 170 | 16.1% | 9.4% | 13.3% | 7.8% | 11.0% | 6.4% |
| 140 | 31.0% | 16.8% | 23.9% | 13.3% | 18.7% | 10.6% |
| 110 | 120.4% | 46.5% | 65.9% | 30.6% | 43.1% | 21.7% |
| 90 | — | — | — | 101.0% | 142.0% | 50.0% |

In this case, the highest luminance-improvement rate (142%) is marked in the case where the transparent electrode 30 has a size of a 90 μm square, the diameter of the pad electrode 32 is 90 μm, and the diameter of the flattened ball is 60 μm. The luminance-improvement rate was approximately 150% in this experimental trial.

Specifically, in the first to third embodiments, the diameter of the flattened ball can be reduced by increasing the adhesion strength of the wire bonding. Therefore, the size of the pad electrode 32 can be downsized. In addition, the light transmittance of the pad electrode 32 is settable at 30% or higher. Accordingly, even if the size of the transparent electrode 30 is reduced to be equal to the outer diameter of the pad electrode 32, a high luminance can be secured. In this way, the chip size can be reduced easily.

Table 4 shows the improvement effect of luminance in the cases where the diameter of the flattened ball is further reduced. The light-transmittance of the pad electrode 32 is set to 70% in accordance with the second or third embodiment.

TABLE 4
TRANSMITTANCE: 70%

| SIZE OF | BALL | | BALL | | BALL | |
|---|---|---|---|---|---|---|
| TRANS- | DIAMETER: | | DIAMETER: | | DIAMETER: | |
| PARENT | 60 μm | | 50 μm | | 40 μm | |
| ELECTRODE | PAD DIAMETER (μm) | | | | | |
| (μm) | 90 | 80 | 80 | 70 | 70 | 60 |
| 250 | 4.4% | 2.7% | 3.7% | 2.2% | 3.1% | 1.8% |
| 200 | 7.4% | 4.4% | 6.1% | 3.6% | 5.0% | 3.0% |
| 170 | 11.0% | 6.4% | 9.0% | 5.3% | 7.2% | 4.2% |
| 140 | 18.7% | 10.6% | 14.7% | 8.4% | 11.5% | 6.6% |
| 110 | 43.1% | 21.7% | 30.3% | 16.0% | 22.0% | 11.9% |
| 90 | 142.0% | 50.0% | 69.7% | 31.0% | 42.6% | 20.8% |
| 70 | — | — | — | 152.2% | 172.1% | 53.0% |

The highest luminance-improvement rate (172.1%) is marked in the case where the transparent electrode 30 has a size of a 70 μm square, the diameter of the pad electrode 32 is 70 μm, and the diameter of the flattened ball is 40 μm. Accordingly, even if the size of the chip is reduced to 140 μm×140 μm, for example, the luminance is approximately 25% higher than the luminance of a light-emitting device having a chip size of 250 μm×250 μm.

Table 5 shows the results of a reliability test of the light-emitting devices according to the first to third embodiments.

TABLE 5

| | CYCLE | | | | | | | |
|---|---|---|---|---|---|---|---|---|
| EXAMPLE | 100 | 200 | 300 | 400 | 500 | 1000 | 1500 | 2000 |
| COMPARA- | 1/20 | 4/20 | 8/20 | 20/20 | — | — | — | — |
| TIVE | | | | | | | | |
| EXAMPLE | | | | | | | | |
| FIRST | 0/20 | 0/20 | 0/20 | 0/20 | 0/20 | 0/20 | 0/20 | 0/20 |
| EMBODI- | | | | | | | | |
| MENT | | | | | | | | |
| SECOND | 0/20 | 0/20 | 0/20 | 0/20 | 0/20 | 0/20 | 0/20 | 0/20 |
| EMBODI- | | | | | | | | |
| MENT | | | | | | | | |
| THIRD | 0/20 | 0/20 | 0/20 | 0/20 | 0/20 | 0/20 | 0/20 | 0/20 |
| EMBODI- | | | | | | | | |
| MENT | | | | | | | | |

In a temperature cycle test, the temperature was repeatedly raised from −40° C. to 110° C. and lowered from 110° C. down to −40° C. As a result of the test, all 20 devices of the comparative example in which the pad electrode 32 has a thickness of 20 nm experienced open failure after 400 cycles. In contrast, none of the light-emitting devices according to the first to third embodiments experienced open failure even after 2000 cycles.

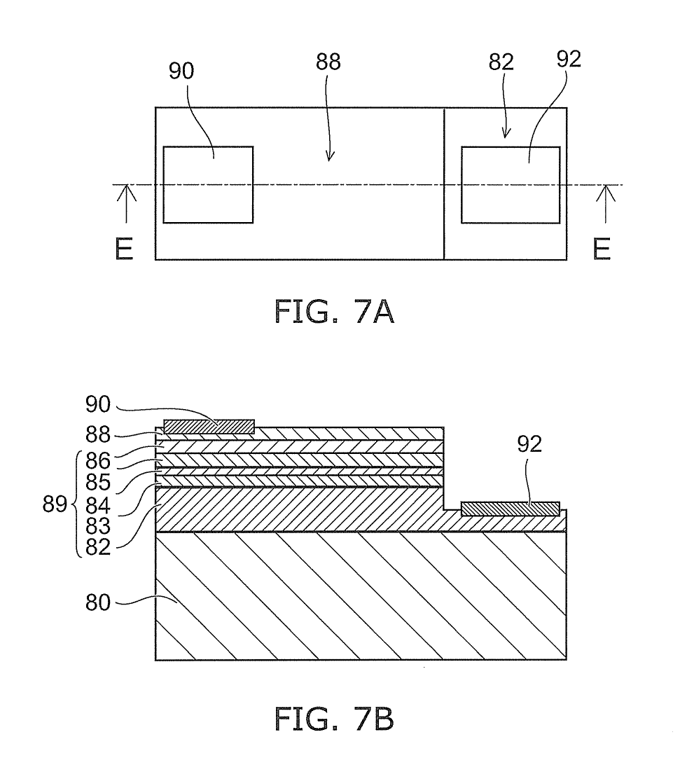

FIG. 7A is a schematic plan view of a fourth embodiment, and FIG. 7B is a schematic cross-sectional view taken along line E-E.

In a nitride-based device made of InGaAlN, a semiconductor stacked body 89 is formed on a transparent or opaque substrate 80. The semiconductor stacked body 89 includes a contact layer 82, a cladding layer 83, a light-emitting layer 84, a cladding layer 85, a contact layer 86, and the like. Sapphire or ZnO may be used for a transparent substrate, and a Si substrate or the like may be used for an opaque substrate. Because the lattice constants of both the substrates are so different, various techniques are applied to improve the light-emitting efficiency. For example, a process of forming a buffering layer and the plane orientation of the substrate 80 may be selected adequately. In addition, the substrate 80 itself may be processed to have a periodic structure with protruding and recessed portions at a pitch of several tens of micrometers. In this case, a pad electrode 90 and a lower-portion electrode 92 are provided at the same side of the substrate 80. At least the pad electrode 90 above the light-emitting layer 84 is one of the pad electrodes of the first to the third embodiments. Needless to say, the lower-portion electrode 92 of the opposite conductivity type may have the pad-electrode structure of this embodiment. Note that a transparent electrode may be additionally provided between the lower-portion electrode 92 and the contact layer 82.

In this case, the chip may be bonded to the package by a flip-chip structure using bumps of solder balls, Au balls, or the like. If a light-reflecting layer is provided on the bonding-surface side of the package, the light transmitted through the pad electrode 90 and the lower-portion electrode 92 can be reflected upward or toward the sides. Accordingly, the light-extraction efficiency can be enhanced even more.

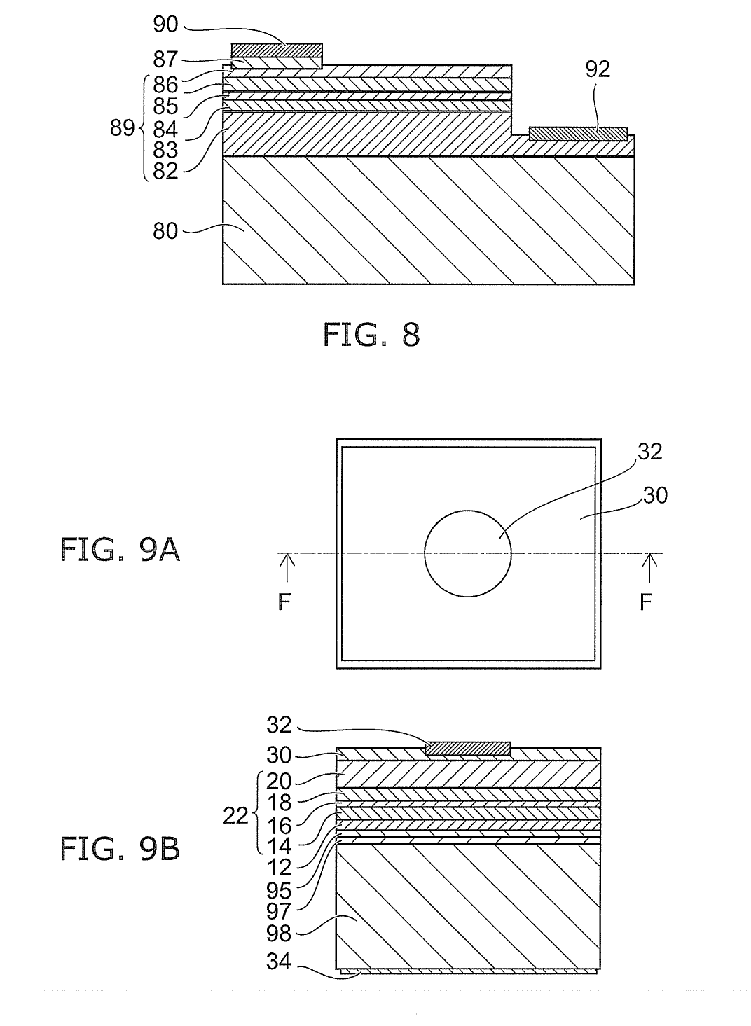

FIG. 8 is a schematic cross-sectional view of a fifth embodiment.

Specifically, a light-emitting device of FIG. 8 has a structure in which no transparent electrode is provided. In this structure, an ohmic contact may be formed between an ohmic electrode 87 and a pad electrode 90. In this case, protruding portions may be provided on the surface of the semiconductor stacked body 89. If a conductive substrate is used as a substrate 80, a lower-portion electrode 92 can be provided on the back-surface side of the substrate 80.

In the case where no transparent electrode is provided and the pad electrode 90 has an island shape, no carriers are injected into the semiconductor stacked body 89 from the islands located in an area not connected to the flattened bonding wire. Accordingly, the optical output is decreased. On the other hand, in the case where the pad electrode 90 has a mesh-like shape, the reduction of the carrier injection can be suppressed.

In the fifth embodiment, the diameter of the flattened ball can be reduced by enhancing the bonding strength of the wire bonding. Thus, the light blocking amount of the pad electrode 90 can be reduced by decreasing the size of the pad electrode 90. In addition, the light transmittance of the pad electrode 32 can be set to 30% or higher, and a higher luminance can be secured. Consequently, the chip size can be reduced easily.

FIG. 9A is a schematic plan view of a sixth embodiment, and FIG. 9B is a schematic cross-sectional view taken along line F-F.

A semiconductor stacked body 22 can be bonded to a substrate 98, which is not a crystal growth substrate, by wafer bonding via a bonding layer 97. In this case, a reflection layer 95 can be provided easily between the semiconductor stacked body 22 and the bonding layer 97. Accordingly, the light-extraction efficiency can be further enhanced.

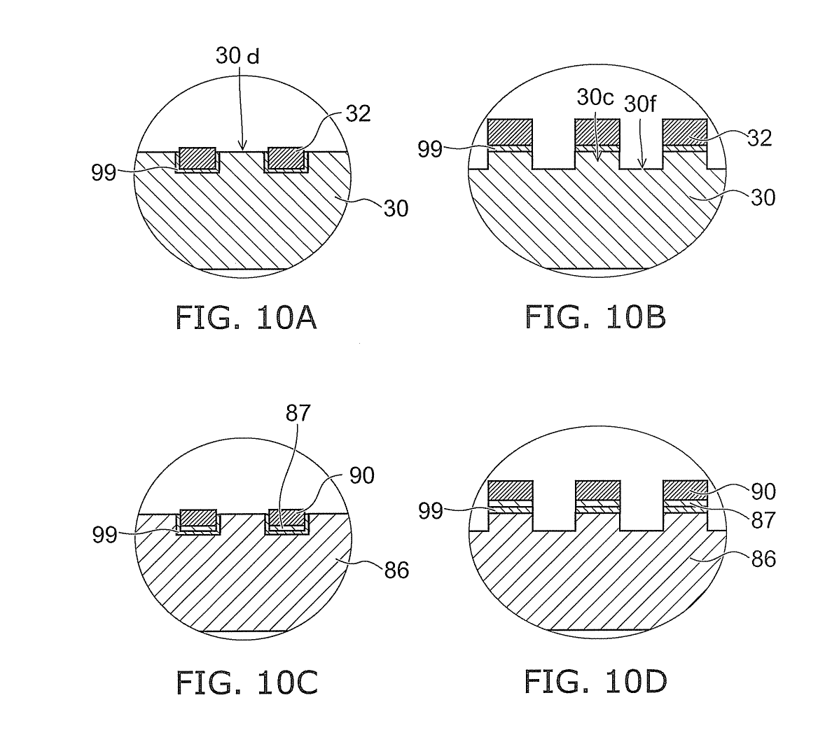

FIGS. 10A to 10D are schematic cross-sectional views of an alloy layer.

A thin alloy layer 99 is formed by a heat treatment at a temperature of approximately 300° C. to 500° C. between a pad electrode 32 and a transparent electrode 30 made of ITO or the like or between a pad electrode 90 and an ohmic electrode 87. Even if the thickness of the pad electrode 32 is as small as 20 nm, the alloy layer 99 is formed and absorbs light. In the second embodiment shown in FIG. 10A and in the third embodiment shown in FIG. 10B, the alloy layer 99 is formed only in an area in contact with the pad electrode 32 and is not formed on the top surface 30c and on the bottom surface 30f through which light passes. Accordingly, the light absorption can be reduced. In addition, FIGS. 10C and 10D show the alloy layer 99 in the case where no transparent electrode is provided.

In the light-emitting devices according to the first to the sixth embodiments, the light transmittance of the pad electrode and the wire bonding strength are enhanced, and this enables production of light-emitting devices that can be easily reduced in size while securing a high luminance. As a result, the mass-productivity of the light-emitting device chips can be improved, and the cost can be lowered accordingly. Such light-emitting devices may be used widely as lighting apparatuses, display apparatuses, traffic lights, and the like.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

1. A light-emitting device comprising:
a semiconductor stacked body having a surface and including a light-emitting layer, the surface having protruding portions; and
a pad electrode provided on one of a top surface of the protruding portions and a bottom surface around the protruding portions.

2. The device according to claim 1, further comprising:
an alloy layer provided between the pad electrode and the semiconductor stacked body.

3. The device according to claim 1, wherein
the protruding portions are island-shaped or mesh-shaped, and
an average pitch of the island-shaped protruding portions or an average pitch of the bottom surface around the mesh-shaped protruding portions is within a range from 10 nm to 3 μm.

4. The device according to claim 1, wherein
the pad electrode is provided on the top surface of the protruding portions, and
the semiconductor stacked body is exposed at the bottom surface.

5. The device according to claim 1, wherein
the pad electrode is provided on the bottom surface,
a thickness of the pad electrode is larger than a height of the protruding portions, and
the top surface of the protruding portions includes the semiconductor stacked body.

6. The device according to claim 1, wherein the pad electrode is provided on the top surface of the protruding portions and on the bottom surface of the protruding portions.

7. A light-emitting device comprising:
a semiconductor stacked body including a light-emitting layer;
a transparent electrode having a first surface and a second surface, the first surface having protruding portions, the second surface being in contact with the semiconductor stacked body and being capable of providing an ohmic contact; and
a pad electrode provided on one of a top surface of the protruding portions of the first surface and a bottom surface around the protruding portions of the first surface.

8. The device according to claim 7, further comprising:
an alloy layer provided between the pad electrode and the transparent electrode.

9. The device according to claim 7, wherein
the pad electrode is provided on the top surface of the protruding portions, and
the transparent electrode is exposed at the bottom surface.

10. The device according to claim 9, wherein
the protruding portions are island-shaped or mesh-shaped, and
an average pitch of the island-shaped protruding portions or an average pitch of the bottom surface around the mesh-shaped protruding portions is within a range from 10 nm to 3 μm.

11. The device according to claim 7, wherein
the pad electrode is provided on the bottom surface,
a thickness of the pad electrode is larger than a height of the protruding portions, and
the top surface of the protruding portions includes the transparent electrode.

12. The device according to claim 11, wherein
the protruding portions are island-shaped or mesh-shaped, and
an average pitch of the island-shaped protruding portions or an average pitch of the bottom surface around the mesh-shaped protruding portions is within a range from 10 nm to 3 μm.

13. The device according to claim 7, wherein the pad electrode is provided on the top surface of the protruding portions and on the bottom surface of the protruding portions.

14. The device according to claim 13, wherein
the protruding portions are island-shaped or mesh-shaped, and
an average pitch of the island-shaped protruding portions or an average pitch of the bottom surface around the mesh-shaped protruding portions is within a range from 10 nm to 3 μm.

15. The device according to claim 13, wherein the pad electrode is continuous over the top surface of the protruding portions and the bottom surface of the protruding portions.

16. A light-emitting device comprising:
a semiconductor stacked body having a first-conductivity-type layer, a second-conductivity-type layer and a light-emitting layer provided between the first-conductivity-type layer and the second-conductivity-type layer;
a first transparent electrode having a first surface and a second surface, the first surface having protruding portions, the second surface being contact with the semiconductor stacked body and being capable of providing an ohmic contact;
a pad electrode provided on one of a top surface of the protruding portions of the first surface and a bottom surface around the protruding portions of the first surface; and
a lower-portion electrode provided on the first-conductivity-type layer exposed to a bottom surface of a step difference provided in the semiconductor stacked body.

17. The device according to claim 16, further comprising:
an alloy layer provided between the pad electrode and the first transparent electrode.

18. The device according to claim 16, wherein
the protruding portions are island-shaped or mesh-shaped, and
an average pitch of the island-shaped protruding portions or an average pitch of the bottom surface around the mesh-shaped protruding portions is within a range from 10 nm to 3 μm.

19. The device according to claim 16, wherein the semiconductor stacked body is made of InₓGa_{y}Al_{1-x-y}N (0≦x≦1, 0≦y≦1, x+y≦1).

20. The device according to claim 16, further comprising:
a second transparent electrode provided between the lower-portion electrode and the bottom surface of the step difference;
the second transparent electrode having a first surface and a second surface, the first surface having island-shaped or mesh-shaped protruding portions, the second surface being in contact with the first-conductivity-type layer and being capable of providing an ohmic contact,
the lower-portion electrode being provided on one of a top surface of the protruding portions of the first surface of the second transparent electrode and the bottom surface around the protruding portions of the first surface of the second transparent electrode.
